(19) United States
(12) Patent Application Publication
(10) Pub. No.: US 2012/0161783 A1
(43) Pub. Date: Jun. 28, 2012

(54) DRY GEL-CONDUCTIVE SCAFFOLD SENSOR

(75) Inventors: Christine Berka, Carlsbad, CA (US); Daniel J. Levendowski, Carlsbad, CA (US); Giby Raphael, San Marcos, CA (US); Djordje Popovic, San Diego, CA (US); Catherine N. Skelton, Fallbrook, CA (US); Jamshid Avloni, Moraga, CA (US); Nattharika Aumsuwan, Fairfield, CA (US)

(73) Assignee: ADVANCED BRAIN MONITORING, INC., Carlsbad, CA (US)

(21) Appl. No.: 13/333,600

(22) Filed: Dec. 21, 2011

Related U.S. Application Data
(60) Provisional application No. 61/425,642, filed on Dec. 21, 2010.

(51) Int. Cl. G01R 27/00

(52) U.S. Cl. 324/600

(57) ABSTRACT

A dry gel-conductive sensor. In embodiments, the sensor comprises a scaffold structure which comprises a structure and a covering. A conductive material, which is both ionically and electronically conductive, may be dispersed within the structure. According to an embodiment, the covering comprises openings which allow conductive material through the covering to contact the skin of a subject. The covering may additionally or alternatively comprise brush-like features configured to penetrate through hair.

### PRIORITY CLAIM

This application claims priority to U.S. Provisional Patent App. No. 61/425,642, filed on Dec. 21, 2010, titled “Conductive Textile Sensor for Physiological Recordings,” the entirety of which is hereby incorporated herein by reference.

### FIELD OF THE INVENTION

This application generally relates to sensors for obtaining physiological measurements, and to semi-dry sensors capable of continued use and which provide for both ionic and electronic conduction.

### BACKGROUND

Conventional electroencephalography (EEG) acquisition relies on a low mass, non-polarizable Ag/AgCl electrode with a layer of gel, cream, or other electrically conductive material (“gel”) applied between the skin and the electrode. This is generally referred to as a “wet electrode,” and has many disadvantages such as: 1) it is time consuming, especially in applications requiring a large number of electrode sites; 2) prevents self-application of the electrodes without the help of a technician; 3) gel tends to spread laterally, which can create short circuits between electrodes (especially if a large number of densely packed electrodes are used); 4) the gel is messy, difficult to remove from the hair, and in some cases even causes skin irritability, and 5) usage time is limited due to desiccation of the gel. In clinical or research settings, where there are sufficient time and people dedicated for the setup, the impact of these problems are low. However, in other consumer and field applications based on EEG, these disadvantages can mount up to make the conventional “wet electrode” technology unusable.

Wet or bio-potential electrodes, by definition, provide an interface between the body and the electronic measuring apparatus. Because biological currents (i.e., those in the body) are carried by ions, whereas the current in the electrode and its lead wires is carried by electrons, the electrode must serve as a transducer to change an ionic current into an electronic current. In a typical case—that of a metal electrode in contact with an ion-rich solution—the transduction is accomplished by the chemical reactions at the metal-electrolyte interface. When a piece of metal is dipped in an electrolyte, chemical reactions (e.g., reduction-oxidation or “REDOX”) occurring spontaneously at the metal-electrolyte interface will cause one type of charge to become dominant on the surface of the metal, and the opposite type of charge to become distributed in excess in the thin layer of the electrolyte immediately adjacent to the metal. The separation of charge (called “electric double layer”) effectively creates an electric field, which results in a constant potential difference between the metal and electrolyte (commonly known as an equilibrium or “half-cell” potential).

When there is no net current flow at the interface, the reactions still occur but the net transfer of charge across the interface is zero and the half-cell potential remains fairly constant. However, when current flows through the interface, depending on its direction, i.e. electrode to electrolyte vs. electrolyte to electrode, the oxidation or reduction reaction dominates and the half-cell potential is altered. The difference between the observed half-cell potential and the equilibrium half-cell potential is called “overpotential.” The factors that contribute to overpotentials are: 1) the resistance of the electrolyte that sometimes varies nonlinearly with the magnitude of current when the ionic concentrations are low; 2) the difference in the concentration of cations and anions due to the difference in the rate of oxidation and reduction reaction as biased by the current flow; and 3) in some cases, the difference in barrier or activation energy of cations and anions for charge transfer. All these factors add up to produce a net change in half-cell potential from equilibrium during current flow.

Electrically, the half-cell potential can be modeled as a battery (e.g., DC source) in series with the capacitance of the electric double layer and the resistance of the electrolyte. In addition, the capacitor is shunted with another resistor that represents the leakage channels in the dielectric, which effectively brings down the low frequency impedance of the interface to some extent. In perfectly polarizable electrodes such as the ones made with inert noble metals (e.g., gold, silver, platinum, etc.) no actual charge transfer happens at the interface even during the current flow. Thus, the electrode behaves as though it was a capacitor and the current transfer happens by displacement of charge. This capacitive effect considerably increases the impedance at low frequencies and makes the electrode highly susceptible to movement artifacts due to the disturbances in the dielectric. All metal electrodes in contact with body fluids and the scalp essentially suffer from the effects of this unwanted capacitor.

On the other hand, a silver/silver chloride (Ag/AgCl) electrode practically approaches the characteristics of a perfectly non-polarizable electrode and easily allows passage of current across the electrode-electrolyte interface. The silver atoms on the electrode surface are oxidized in the electrolyte, which immediately combine with Cl⁻ ions, forming AgCl that adheres back to the electrode. This considerably reduces the capacitive effect of the electric double layer and improves low frequency impedance as well as resistance to movement artifacts.

The conductive gel used in the wet electrode approach helps ionic transduction in two ways. First, Ag/AgCl electrodes surrounded with a gel rich in CF ions forms an electric double layer, as described above, and the potential difference between the scalp surface and the neutral acquisition circuitry drives a current through the electrode-electrolyte interface. The current alters the half-cell potential at the interface from its equilibrium (ionic current) which sets in motion the electrons in the metallic leads (electronic current). Thus, the time varying electrical potential at the scalp is effectively transduced to electronic current in the data acquisition circuitry.

The second, less prominent effect is at the interface between the gel and the scalp, which in itself forms another half-cell potential due to the difference in ionic concentration between the gel and the epidermis through the semi-permeable outer layer (stratum corneum). The ionic exchange between the electrolyte-scalp interface also helps in transduction by reducing the capacitive effect of the interface. Abrading the skin, thus removing the outer high impedance layer, provides the best results against the attenuation effects of the outer layer. However, this is not always practical.

The reduced capacitance improves the low frequency impedance and resistance to movement artifacts of the interface. Gel also helps in other ways. For instance, viscous gel, unlike flat metal electrodes, when used in the right amount, always forms a stable, conductive path with the uneven skin surface. Thus, the change in contact surface area is minimized during relative movement. The gel also acts as a buffer to absorb mechanical vibrations, which again reduces the electrode's sensitivity to motion artifacts.

An alternative to a wet electrode is the “dry electrode” approach. Dry electrodes do not use gel. Instead, the body with its ions serves as the electrolyte, and the coupling between the metal (or more generally, conductive surface of the electrode) and the body is purely capacitive (in a broader sense). Dry electrodes are typically divided into two classes: contact and non-contact (referred to in the literature as “capacitive” in a narrower sense). The difference with respect to details of the transduction mechanism is that contact dry electrodes rely, at least in part, on sweat as its “gel.” In conjunction with their intimate contact to the skin, this allows for the electrode-skin impedance to be reduced to the level of Mega-ohms (as compared to Giga-ohms for non-contact dry electrodes). Irrespective of this difference, dry electrodes may have the following shortcomings:

1. High source impedance.

All dry-electrodes that do not exploit ion exchange at the skin interface can be collectively classified as perfectly polarizable or capacitive electrodes. Thus the electrode interface behaves like a capacitor. Electrically, this interface can be modeled as a capacitor in series with interface resistance, plus a leakage resistor parallel to the capacitor. It will have high impedance at lower frequencies and also take substantial time to recover from voltage shifts because of a time constant.

In order to maintain the signal amplitude and to avoid distortion, the input impedance of the preamplifier should be sufficiently greater than the source impedance. Instrumentation amplifiers with input buffers by default have high input impedances and it is well known that when the operational amplifier is used in a non-inverted configuration, the input impedance is multiplied by the gain. Thus, ultra high input impedance of the preamplifier in the Mega-Ohm ranges can easily be achieved. This technique is used in all current dry electrode implementations.

However, when using the preamplifier in high-gain configurations, special care should be taken to avoid saturation of the amplifier. The bias current could amplify noise in the feedback resistors of the high-gain preamplifier and also integrate at the input capacitors, or run through the high impedance interface to produce DC offsets on the capacitive electrodes to the order of 20-30 mV. “A low-noise, non-contact EEG/ECG sensor,” Biomedical Circuits and Systems Conference, 2007, by Sullivan et al. (“Sullivan et al.”), which is hereby incorporated herein by reference, describes a transistor-based reset circuitry in the input buffer to detect and discharge over-potentials. Some other implementations use preamplifiers with high dynamic ranges in order to acquire both EEG and offset. The offset can then be canceled out later digitally.

2. External interferences (EM, 60 Hz etc).

Another classification of the EEG systems is as passive or active. Passive systems have the preamplifier located a finite distance from the electrodes. The leads used to attach the electrodes to the preamplifier can have lengths varying from a few millimeters up to many inches around the circumference of the head. Thus, electromagnetic interferences (EMI) from various sources and the 60 Hz power hum from other appliances and conductors could capacitively couple to the exposed leads. The high input impedance of the preamplifiers does not allow any current to flow into the amplifier. However, the current could flow through the electrodes and the body and show up as noise in the preamplifier. Since the preamplifiers have a high common-mode rejection ratio (CMRR), any such noise is rejected. But if there is any impedance mismatch between the inputs at the electrode sites, the noise current will be multiplied by the difference in impedances. Also, since all of these preamplifiers are used in high-gain configurations to boost the input impedance, the noise will be amplified.

Passive dry electrode systems—such as those described in “A mobile EEG system with dry electrodes,” 2008, by Gargiulo et al., which is hereby incorporated herein by reference—take care of this problem by shielding their conductors (e.g., double layer shielding). However, since the system is battery-powered (floating ground), the interference on the shield cannot be dissipated to the device ground, but instead, is driven back inverted to the right ear lobe using a Right Leg Driver circuit to cancel out the common mode. The driver circuit also helps in reducing other common-mode signals such as those coupled directly to the body.

Active electrode systems—such as those described in “A novel dry active electrode for EEG recording,” IEEE trans. in Biomedical Eng., 2007, by Fonseca et al., which is hereby incorporated herein by reference—solve the interference problem by placing an active buffer close to the electrode site, thus, not requiring strong shielding. The output impedance of the buffer amplifiers is in the order of a few ohms. Thus, the impedance mismatch is negligible on the second stage amplifier connected to the leads. Sullivan et al. implemented both active shielding and coupled it with active buffering in order to cut off interferences more effectively.

3. Movement artifacts.

Almost all consumer and field applications of EEG need the system to work in spite of some movement between the electrodes and the skin. Current dry electrode technologies largely fail in this regard. Many are focused on frequencies at alpha (8-10 Hz) and higher bandwidths, and most of the publications neglect testing under mobile conditions. All capacitive dry electrodes work based on displacing the charge in the dielectric. Thus, any displacement in the dielectric would show up as noise in the acquired signal. This effect is even worse in active electrodes as the components increase the mass—and thus inertia—of the electrode.

Wet electrodes, on the other hand, form ionic paths at the interface, and thus reduce this capacitive effect considerably. The half-cell potential at the interface formed by the chemical reactions cause some deterioration in the signal, but relatively, it is much more robust to movement artifacts. Insulating electrodes that use air as the dielectric perform relatively better than other dry electrodes, but the low capacitance of these electrodes in itself creates other problems due to ultra-high source impedance and high gain in the preamplifiers.

4. Other issues.

Other issues relate to the size, weight, and user comfort of the current dry electrodes. The comfort of dry electrodes that penetrate the upper layer of skin—such as those described in “First human trials of a dry electrophysiology sensor using a carbon nanotube array interface,” Sensors and Actuators A: Physics, Volume 144, Issue 2, 2008, by Ruffini et al., and “Using novel MEMS EEG sensors in detecting drowsiness application,” Biomedical circuits and systems conference, 2006, by Chiou et al., both of which are hereby incorporated herein by reference—is arguable. Also, the bulkiness and hard components of many active electrodes (e.g., Quasar) make them impossible to be embedded under Kevlar for military applications. Moreover, the increase in mass of the electrodes makes them more prone to movement artifacts.

Thus, while the dry electrode is theoretically faster to affix and less messy, after four decades of research, the capability of a dry electrode that can match the signal quality and fidelity of wet electrode is yet to be proven.

Electronic dry sensors.

All electronically conductive dry sensors do not supportionic transduction of the signals. Thus, they are inherently susceptible to the issues described above.

U.S. Pat. No. 6,445,940 to Gevins, which is hereby incorporated herein by reference, describes ceramic single place capacitive electrodes which use ceramic insulator as dielectric. Due to non-conformance with the uneven scalp surface, a layer of air is unavoidably trapped at the scalp interface. The dielectric disturbances could reflect as noise artifacts. The sensors need superior packaging to avoid relative movement and require complicated on-site active circuitry for signal capture, due to high impedance at low frequencies.

In U.S. Pat. No. 5,038,782 to Gevins et al., which is hereby incorporated herein by reference, a dry electrode is described in which multiple metal conductive fingers protrude through the hair to the scalp. Because of the high impedance connection of the electrode tips with the scalp, the electrodes are sensitive to artifacts resulting from head motion.

Ionic dry sensors.

In U.S. Pat. No. 5,817,016 to Subramaniam, which is hereby incorporated herein by reference, a polyacrylate hydrogel with an electrically conductive salt in water solution is described. This hydrogel is suited for biomedical electrodes and sensors. Even though the hydrogel supports ionic conduction, it does not support electronic conduction within the gel and the design is rigid without flexible conductive fabrics. The gels also leaves considerable residue on the scalp.

In U.S. Pat. No. 7,761,131 to Copp-Howland, which is hereby incorporated herein by reference, a conductive hydrogel composition, which does not change its conductive properties significantly when exposed to the atmosphere, is described. This formulation describes a copolymer where the primary monomer is a mixture of acrylic acid and salt and is 80-95 mol %, the second monomer is, preferably, a salt of 2-acrylamido-2-methylpropance sulfonic acid which is 5-20 mol %, and the conductive electrolyte is sodium chloride. This composition claims to be useful in medical, including EEG, electrodes. The sensor does not leverage electronic conduction and does not use a conductive fabric base.

Other designs.

In U.S. Pat. No. 4,709,702 to Sherwin, which is hereby incorporated herein by reference, the electrodes contact the scalp with “tulip probes” having sharp points to “penetrate the dead skin layer.” Such a sharp point tip is medically dangerous due to the possibility of infection and harming the patient.

### SUMMARY

In an embodiment, a conductive sensor is described comprising: an electrically conductive scaffold; and a conductive material that provides for ionic conduction and electrical conduction, wherein the conductive material is dispersed in the conductive scaffold.

In another embodiment, an ionically and electronically conductive sensor is described comprising a conductive scaffold comprising a structure, a covering, and sides; an enclosure encompassing the sides of the conductive scaffold; and a conductive material within the structure of the conductive scaffold, wherein the conductive material provides both ionic and electronic conduction.

### BRIEF DESCRIPTION OF THE DRAWINGS

FIG. 1 illustrates an electronically conductive spacer fabric with open weave function for capturing conductive material, according to an embodiment.

FIG. 2 illustrates a fabric material with brush-like features that provide an electrical pathway to the scalp through hair, according to an embodiment.

FIG. 3 illustrates conductive material in a spacer fabric material with means of integration with a flexible material, according to an embodiment

FIGS. 4a and 4b illustrate conductive material attached to conductive fabric, according to an embodiment.

FIGS. 5a and 5b illustrate conductive material attached to conductive fabric, according to an embodiment.

FIGS. 6a and 6b illustrate conductive material attached to conductive fabric, according to an embodiment.

FIG. 7 illustrates beta electroencephalographic (EEG) activity from a subject seated and alert with eyes open, as measured by an embodiment.

FIG. 8 illustrates alpha EEG activity from a subject seated and relaxed with eyes closed, as measured by an embodiment.

FIG. 9 illustrates a frequency domain representation of signals, as measured by an embodiment.

FIG. 10 illustrates the results of correlation and cohesion testing between sensors using embodiments of the disclosed conductive material and a standard Ag/AgCl sensor with conductive cream.

### DETAILED DESCRIPTION

Embodiments described here pertain to a “dry gel-conductive scaffold sensor” that has all the desirable properties of conductive gel (e.g., soft, shock absorbing, highly conductive, and containing chloride ions that create a very low impedance contact with a subject's scalp), but which leaves no residue and can endure continued use for weeks, and perhaps months. The conductive material provides for both ionic and electrical/electronic conduction in a semi-dry form factor that is also resistant to dehydration through other chemicals. Embodiments can be used in electroencephalography (EEG) acquisition. Certain embodiments comprises elements that address the current limitations of both wet and dry sensors. The sensor may contain a conductive element containing chloride ions that provides low impedances when interfaced to the scalp or skin, without the need to abrade or prepare the skin or scalp. It may have the desirable properties of conductive gel/hydrogel (e.g., soft, light weight, adjusting to uneven surface areas, leaving no residue), but is superior because it remains conductive for weeks, and perhaps months after exposure to air.

The conductive element can be incorporated in or applied to any number of materials to assist in the placement on the head or body, and to create the electronic pathway to acquire the physiological signal. In one embodiment, the conductive element can be affixed to conventional electrodes. In another embodiment it can be applied to textile or fabric with conductive thread providing the electrical pathway to the amplifiers.

The conductive element can be incorporated into an electrically conductive scaffolding to further improve the desirable features of the invention. The type of material, thickness, and features of the scaffolding may be dependent, in part, on the expected physical location where the signals are to be acquired. For example, the scaffolding that one may use to bridge the conductive material to the scalp through hair might be uncomfortable if applied to the forehead. Conversely, the scaffolding that one would use to apply the conductive material to the skin, if applied to hair, would sit on top of the hair, and thus provide a poor conductive pathway.

The selection of material used for the scaffolding could also improve the capability to absorb shock, thus improving the quality of the physiological signal during ambulatory acquisition. Embodiments that include the conductive material and conductive scaffolding can be further enhanced with features that make them resistant to dehydration. This could be accomplished through the addition of chemicals to the conductive material, or the encapsulation of the conductive material and/or conductive scaffolding to reduce exposure to the air. Some embodiments include using the sensor in EEG caps of various designs.

According to an embodiment, conductive material of any shape and size is infused into a conductive scaffold that allows acquisition of high quality physiological signals in either passive or active configuration. The conductive material contained within the conductive scaffold can be integrated with any variety of sensor site stabilizing units, which include but are not limited to:

1. Textile with embroidered conductive thread leads and sensor site pads which adhere to the sensor through one or more conductive hooks and loops; and

2. Polyethylene terephthalate (PET) with one or more conductive hooks and loops adhered to the sensor sites for connection to the semi-dry sensor.

The conductive material may include three features. First, the material may utilize elements that provide for ionic conduction. Second, the material may include elements which provide for electrical conduction. Third, the conductive material may be semi-dry, biocompatible to humans, and resistant to dehydration.

In an embodiment, the conductive material incorporates Cl⁻ ions for ionic conduction, and metal flakes and polymer powder for electronic conduction. The Cl⁻ ions help in ionic exchange at the scalp surface similar to wet electrodes. When the Cl⁻ ions are combined with metal atoms, the resulting conductive material provides the characteristics of a perfectly non-polarized electrode, i.e., low capacitive impedance at low frequencies and better resistance to movement artifacts. Other combinations of elements that are used for the conductive material that combines both ionic and electrical conduction include but are not limited to:

1. Hydrophilic polymer gel loaded with inorganic salt (NaCl—ionic conductor) and a high level of moisture;

2. Polyelectrolyte gel loaded with inorganic salt (NaCl—ionic conductor) and metal flakes (electronic conductor);

3. Polyelectrolyte gel loaded with inorganic salt (NaCl—ionic conductor) and conductive polymer (electronic conductor);

4. Polyelectrolyte gel loaded with inorganic salt (NaCl—ionic conductor), metal powder, and conductive polymer (electronic conductors); and

5. Polyelectrolyte gel loaded with inorganic salt (NaCl—ionic conductor), metal powder, and carbon black or graphite (electronic conductors).

There are numerous substitute elements which could be combined to provide the capability obtained by combining both ionic and electrical conductive elements into a single conductive material.

According to an embodiment, the conductive material is incorporated into an electronically conductive scaffold that results in a semi-dry fabric type sensor. The scaffold material may include, but is not limited to:

1. Conductive spacer fabric which can be conductive through metalized or polymer coating and maintains reservoirs of the conductive material;

2. Conductive, open-cell foam which can be conductive through metalized or polymer coating;

3. Conductive polymer cup;

4. A single layer of conductive fabric; and

5. Conductive spacer fabric with a layer of material that has brush-like characteristics with the capability of penetrating through hair.

In embodiments which incorporate brush-like characteristics, the brush-like features that provide contact between the comb and the scalp may be coated with an ionically conductive material. There are a number of fabrics or materials that could be used for conductively coating the fibers or brush-like features, e.g., inherently conductive polymer, carbon fibers, metal flakes, or a combination thereof. Additional examples that can be used for this purpose include:

1. Metal-coated stretchy Lycra® spandex fabric;

2. Metal-coated spacer fabric;

3. Metal/Metal chloride (e.g., Ag/AgCl) coated spacer fabric;

4. Electronically conductive polymer (e.g., doped polypyrrole) coated spacer fabric;

5. Spacer fabric made from carbon fibers; and

6. Spacer fabric coated with a conductive carbonaceous coating.

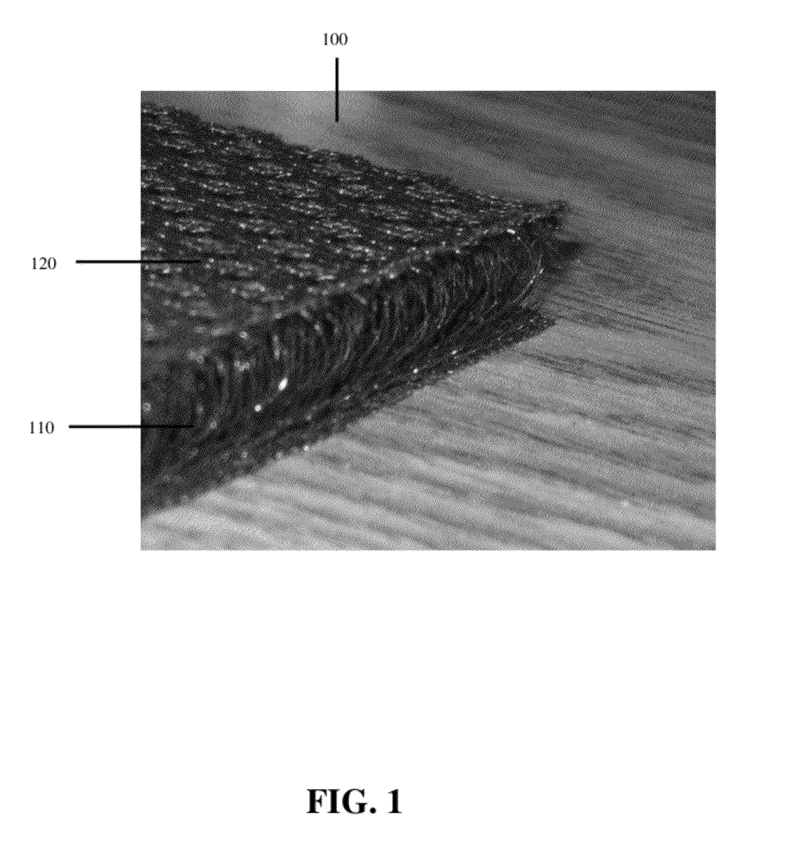

In some embodiments, the scaffold, advantageously, has open weave surfaces, such that gel can come through the openings and make contact with the scalp. For instance, FIG. 1 illustrates an electronically conductive spacer fabric or scaffold 110 with open weave function 120 for capturing the conductive material (not shown), according to an embodiment.

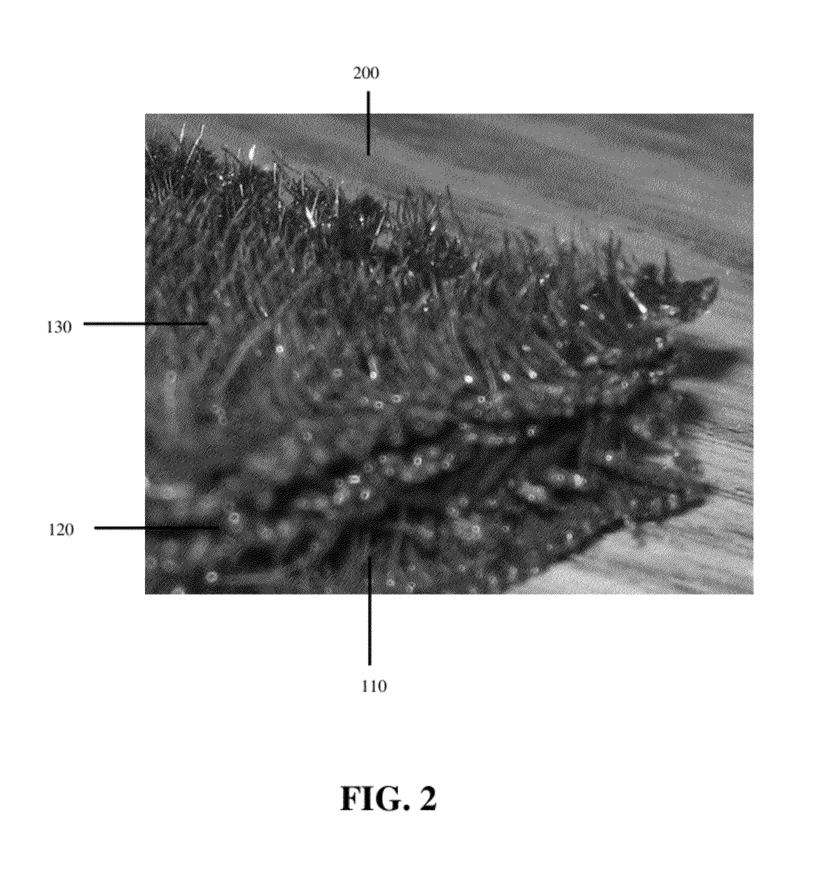

Modifications can be made to this scaffold 110 to create the structure for holding the conductive material and form a semi-dry, infused fabric sensor type. FIG. 2 illustrates an embodiment which uses fabric material with brush-like features 130 to provide an electrical pathway to the scalp through hair. Scaffolding 110 is shown, where a single layer of the spacer fabric 130 is used to create the brush. The brush 130 can be placed against the head to collect EEG data. The double layer spacer fabric 110 below can hold the ionically conductive material (not shown). Protection from the environment can be provided to the conductive material by encompassing the sides of the scaffold and gel electrode in any method of mechanical or chemical enclosure (not shown). This may include encompassing the sides with a closed weave textile or polymer based compound, or through chemical copolymerization.

As described, the sensor combines the characteristics of the conductive gel based wet sensor with superior interface options, while overcoming most of the shortcomings of the typical wet sensor. The sensor of the various embodiments described herein may have one or more of the following nonexclusive advantages:

1. Stable conductivity—the Cl⁻ ions in the conductive material allow excellent transduction of ionic currents associated with the physiological signals similar to the wet sensors;

2. Reduced capacitive conduction with improved resistive conduction through ionic exchange;

3. Good conformance and contact with uneven scalp surfaces, as the stretchy elastic Lycra® fabric and/or compressible spacer fabric can adapt to any complex body/surface geometry;

4. Low contact impedance and better resistance to changes in contact impedance;

5. Excellent transduction of both low (<2 Hz) and high frequency signals;

6. Good shock absorption, and thus, excellent resistance to movement artifacts;

7. Stable but still not rigid mechanical structure through the spacer fabric;

8. Ample reservoir(s) for the conductive material embedded within the fabric in its internal structure;

9. Pressure sensitive dispensing of conductive gel which enables protection of the gel from the environment;

10. Excellent flexibility and specialized comb-like structure that enable penetration through hair;

11. Robust interface to the components associated with data acquisition electronics;

12. Superior user comfort with no hot spots, especially during long hours of monitoring;

13. Continuous use for many days without deterioration in the superior properties of the sensor;

14. Elimination of any hard parts by avoiding on-site amplification, enabling enclosure within other application-specific gear, such as Kevlar caps, videogame headsets, etc.; and

15. No residue left on the scalp or skin following usage.

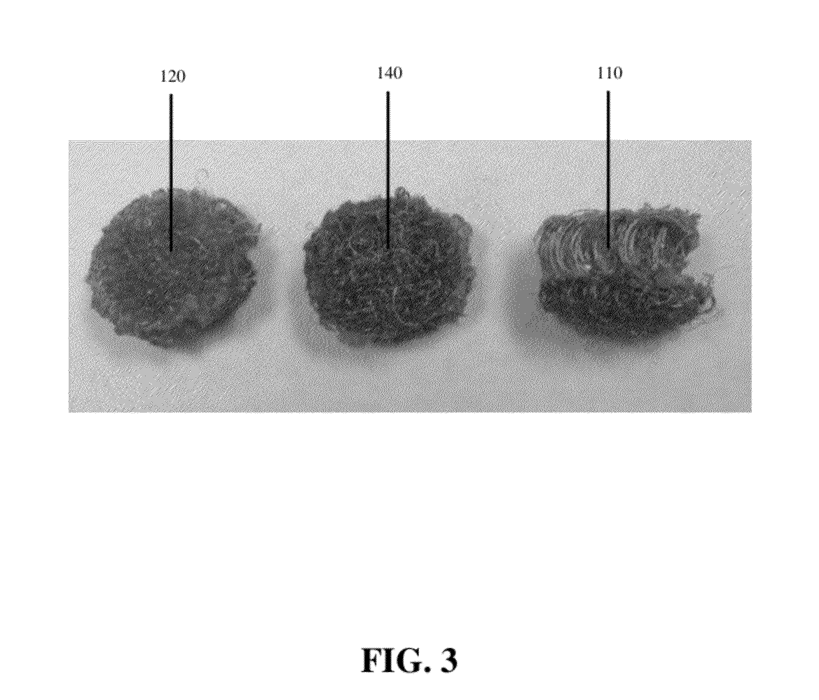

FIGS. 3-6b illustrate several conductive material types. FIG. 3 illustrates the scaffold 110 as a conductive spacer fabric with conductive loops 140 attached for integration of the sensor with a sensor location stabilization unit (not shown). In this figure, the covering 120 provides a surface for contacting the skin of a subject. The covering 120 may comprise a conductive material such as hydrogel. The conductive loops 140, which may comprise Velcro loops, can provide an attachment surface for a sensor site unit (e.g., which may comprise Velcro hooks configured to interface with or attach to the Velcro loops 140). Between the covering 120 and the conductive loops 140 is a scaffold 110 comprising spacer fabric.

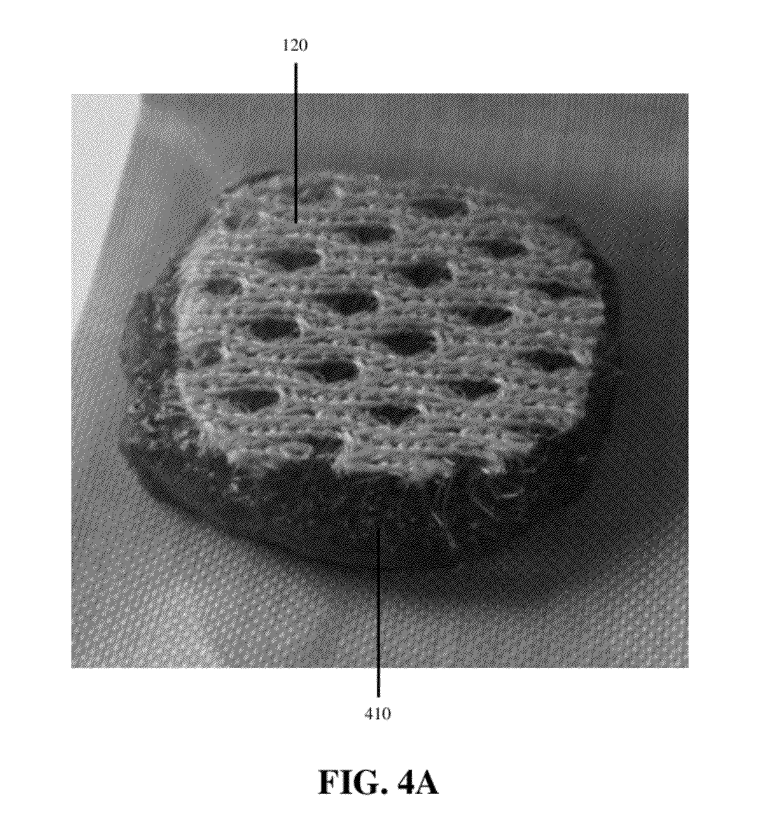

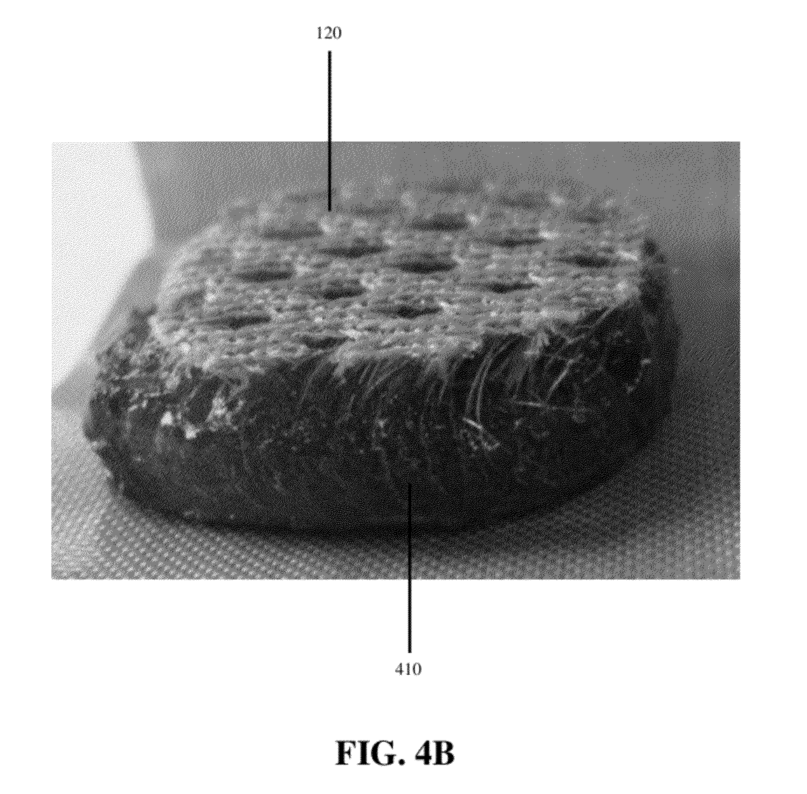

FIGS. 4a and 4b illustrate an example of how the electronically conductive spacer fabric provides scaffolding and environmental protection for the conductive material. The sensor may have full coverage of conductive gel on a cylindrical surface. The scaffold or spacer fabric in this embodiment comprises an open weave fabric surface 120, which is shown disposed on a solid or semi-solid gel or other conductive material 410.

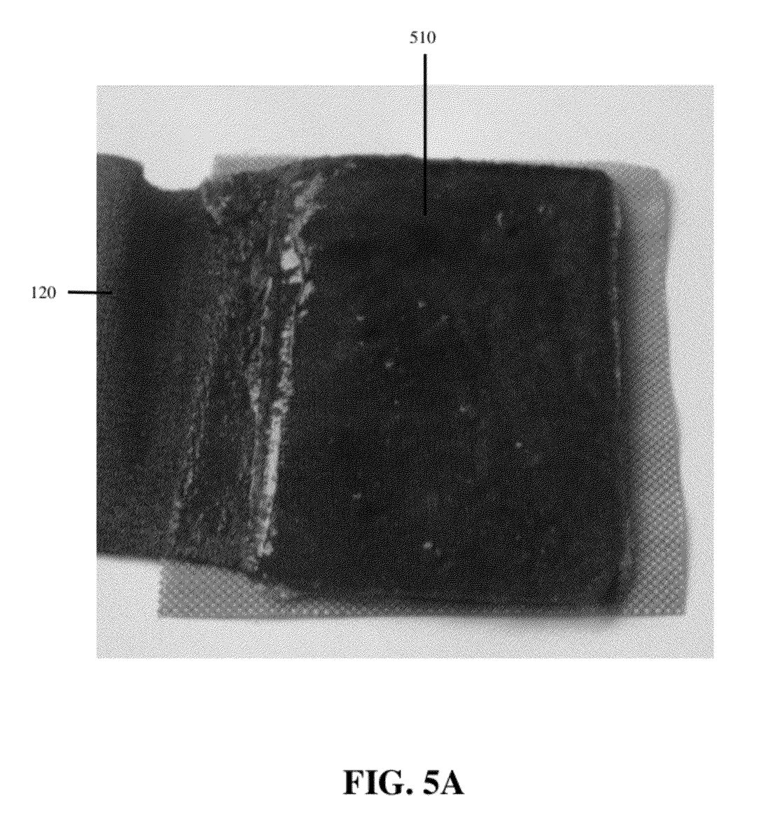

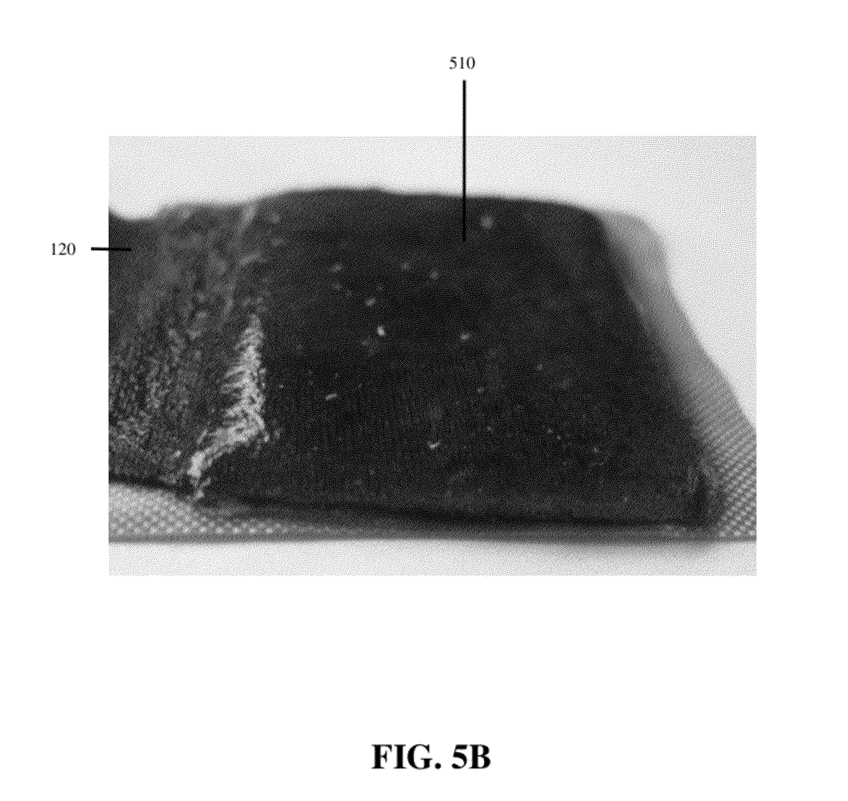

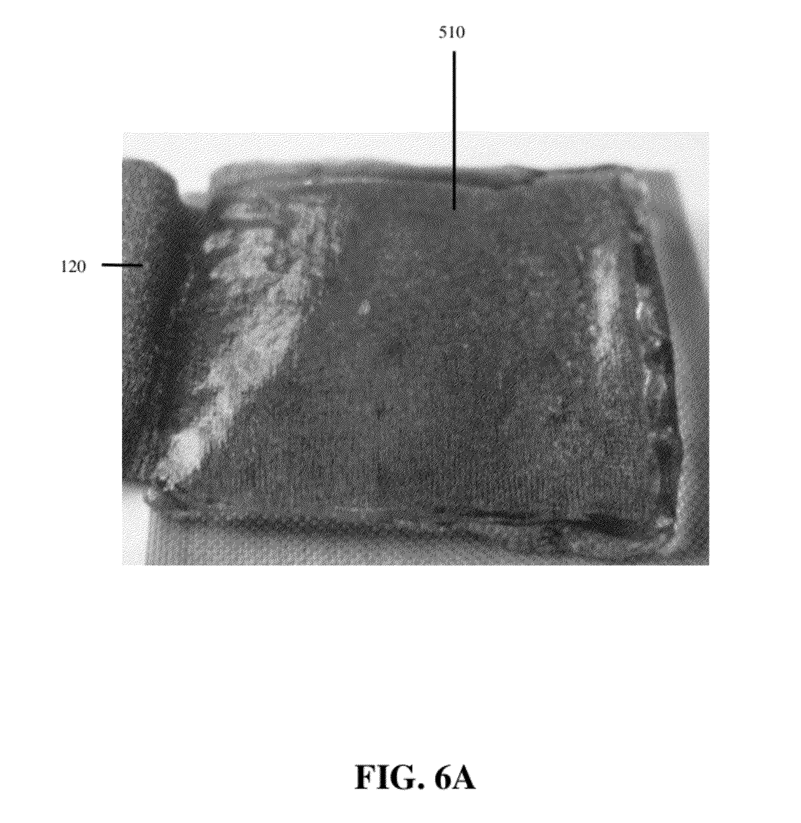

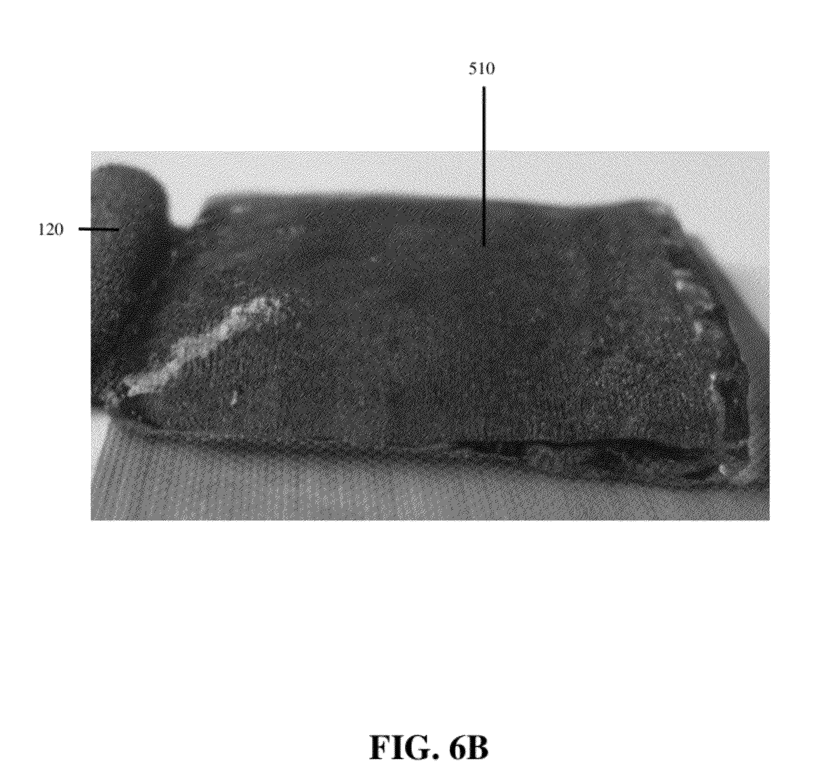

In the embodiments shown in FIGS. 5a-6b, the conductive material 510 is layered on and attached to conductive Lycra® material 120, which servers as the scaffold in this embodiment.

Tests have revealed superior performance of the disclosed sensor when the sensor is applied to skin with no preparation. The resistance between a scalp and sensor (i.e., impedance) was tested using different embodiments of the disclosed sensor. The conductive materials have impedances as little as 2 kΩ.

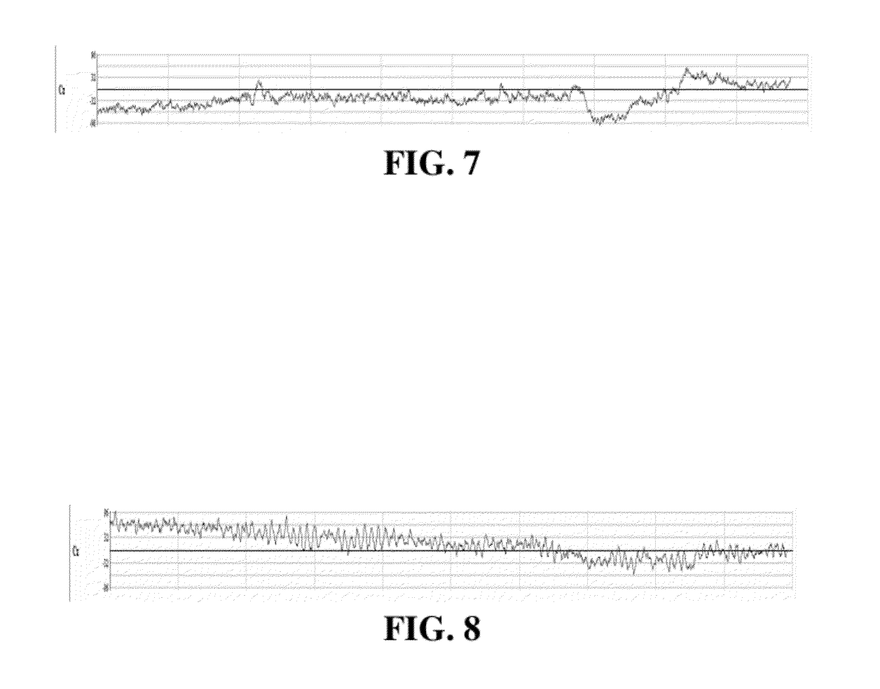

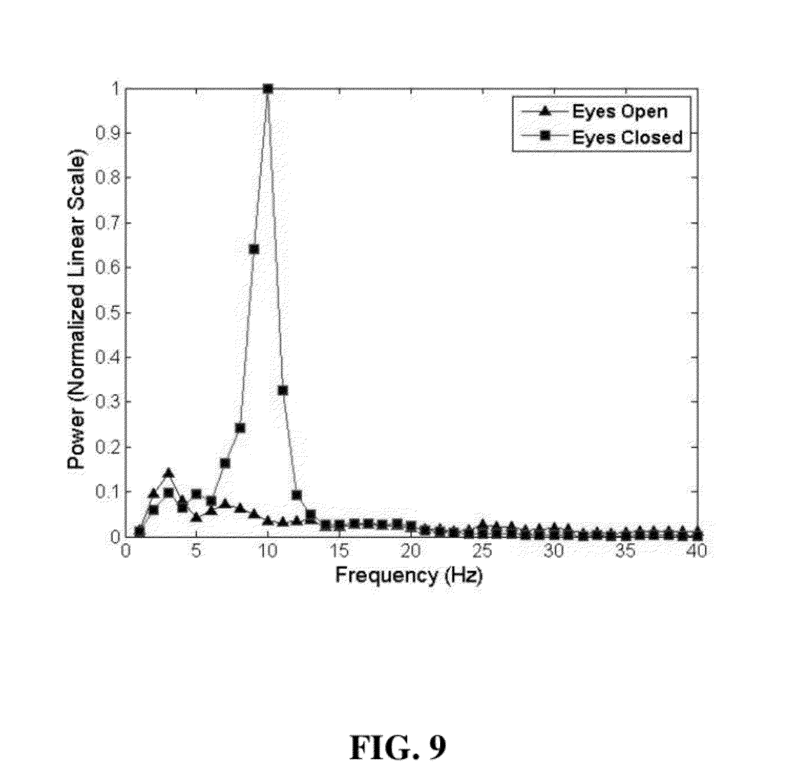

All of the gel options conducted EEG signals well with clear visualization of alpha rhythm in all cases. FIGS. 7 and 8 show clear signals obtained in channel Cz from a sensor using conductive material illustrated in FIGS. 5a and 5b. FIG. 9 shows clear distinction of alpha frequency in the frequency domain.

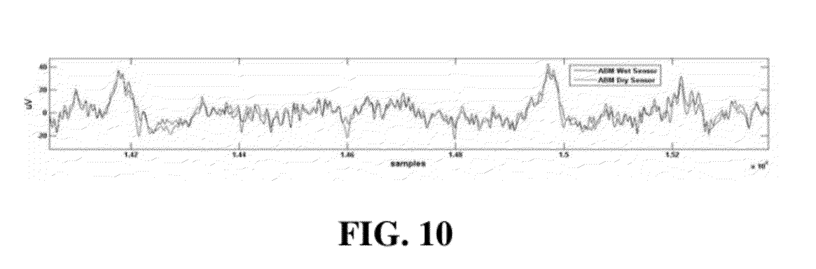

Correlation and cohesion testing was completed where data from conductive material and current Advanced Brain Monitoring foam and cream sensors were collected near the same sites at the same time. As shown in FIG. 10, there was a high average correlation and cohesion between sensors using the conductive material discloses herein and the Ag/AgCl sensor with conductive cream.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention, and are therefore representative of the subject matter which is broadly contemplated by the present invention. It is to be further understood that the scope of the present invention fully encompassed other embodiments that may become obvious to those skilled in the art and that the scope of the present invention is accordingly limited by nothing other than the claims.

What is claimed is:

1. A conductive sensor comprising:
a conductive scaffold; and
a conductive material that provides for ionic conduction and electrical conduction, wherein the conductive material is dispersed in the conductive scaffold.

2. The sensor of claim 1, wherein the conductive scaffold comprises a structure and wherein the conductive material is dispersed within the structure.

3. The sensor of claim 2, wherein the conductive scaffold further comprises a covering which covers at least a portion of the structure.

4. The sensor of claim 3, wherein the covering comprises brush-like fibers.

5. The sensor of claim 4, wherein the brush-like fibers are coated with an ionically conductive material.

6. The sensor of claim 5, wherein the ionically conductive material comprises one or more of conductive polymer, carbon fibers, metal flakes, fabric coated with metal, fabric coated with doped polypyrrole, fabric coated with Ag/AgCl, and fabric coated with a conductive carbonaceous coating.

7. The sensor of claim 3, wherein the covering comprises an open weave surface.

8. The sensor of claim 1, further comprising an enclosure encompassing one or more sides of the conductive scaffold.

9. The sensor of claim 8, wherein the enclosure comprises a closed weave textile.

10. The sensor of claim 8, wherein the enclosure comprises a polymer-based compound.

11. The sensor of claim 8, wherein the enclosure comprises a chemical copolymerization.

12. The sensor of claim 1, wherein the conductive material comprises Cl⁻ ions, metal flakes, and polymer powder.

13. The sensor of claim 1, wherein the conductive material comprises a hydrophilic polymer gel comprising inorganic salt.

14. The sensor of claim 1, wherein the conductive material comprises a polyelectrolyte gel comprising inorganic salt.

15. The sensor of claim 14, wherein the conductive material further comprises one or more of a conductive polymer, metal powder, carbon black, and graphite.

16. An ionically and electronically conductive sensor comprising:
a conductive scaffold comprising a structure, a covering, and sides;
an enclosure encompassing the sides of the conductive scaffold; and
a conductive material within the structure of the conductive scaffold, wherein the conductive material provides both ionic and electronic conduction.

17. The sensor of claim 16, wherein the covering of the conductive scaffold comprises openings configured to allow conductive material through the covering.

18. The sensor of claim 17, wherein the covering of the conductive scaffold further comprises an open weave surface.

19. The sensor of claim 16, wherein the covering of the conductive scaffold comprises brush-like fibers configured to penetrate through hair.
